(19) United States
(12) Patent Application Publication
(10) Pub. No.: US 2010/0268496 A1
(43) Pub. Date: Oct. 21, 2010

(54) SENSOR FOR USE IN AUTOMATION TECHNOLOGY AND METHOD FOR TRANSFERRING CONFIGURATION DATA FROM AN EXTERNAL COMPUTER TO A SENSOR

(75) Inventors: Dennis Trebbels, Neustadt an der Weinstrasse (DE); Heiko Hoebel, Worms (DE); Tobias Bergtholdt, Mannheim (DE)

Correspondence Address: HOFFMAN WARNICK LLC, 75 STATE STREET, 14TH FLOOR, ALBANY, NY, 12207, US

(73) Assignee: PEPPERL + FUCHS GMBH, Mannheim (DE)

(21) Appl. No.: 12/744,096

(22) PCT Filed: Nov. 20, 2008
(86) PCT No.: PCT/EP2008/009844

§ 371 Date: May 21, 2010

(30) Foreign Application Priority Data
Nov. 21, 2007 (EP) 07022631.1

(51) Int. Cl. G01R 19/00; G06F 19/00; G06F 3/00

(52) U.S. Cl. 702/64; 702/189; 710/8

(57) ABSTRACT

The present invention is directed to a sensor for use in automation technology and a method for transferring configuration data from an external computer to a sensor. The sensor includes: a sensor element for measuring a physical variable; a control/evaluation unit for controlling the sensor element, for processing a measuring signal from the sensor element, and for outputting an output signal to a computer interface; wherein the control/evaluation unit includes a memory for storing at least configuration data and program data, the control/evaluation unit cooperating, in an operating mode, with the computer interface for connecting the sensor to a peripheral unit, and wherein the sensor is supplied with electrical energy by the peripheral unit, in the operating mode; wherein the computer interface is adapted for use in a configuring mode for direct connection of the sensor to an external computer; the sensor is supplied with electrical energy by the external computer via the computer interface, in the configuring mode; and the computer interface is adapted to transfer, in the configuring mode, configuration data differentially between the sensor and the external computer through two wires of a data line at a bandwidth of more than 1 MBit/s.

The present invention relates in a first aspect to a sensor for use in automation technology for detecting a measurand, particularly for the detection of objects or articles, as defined in the generic clause of claim 1.

The invention relates in a second aspect to a method for transferring configuration data from an external computer to a sensor for use in automation technology.

A generic sensor has a sensor element for measuring a physical variable and a control/evaluation unit for controlling the sensor element, for processing a measured signal from the sensor element, and for outputting an output signal to a computer interface, and the control/evaluation unit has a memory for the storage of at least configuration data and program data. The computer interface cooperates with the control/evaluation unit and is adapted to connect the sensor to a peripheral unit, in an operating mode, while the sensor is supplied with electrical energy by the peripheral unit, in the operating mode.

Such sensors are known in various forms, for example as inductive, capacitive, or optical sensors, and also as temperature sensors, pressure sensors, fluid level sensors, and position sensors or rotation sensors.

Hitherto, special programming devices have been used for programming and/or configuring the sensors. Usually RS232 or RS485 interfaces are used. However, data transfer is in this case comparatively slow so that an update of relatively large software volumes is cumbersome. In an alternative method, the sensor receives the necessary data by means of intermittent short-circuiting. For this purpose, the sensor is usually disconnected from the peripheral unit to which it is connected during normal measuring operations and the programming device is then connected to the vacant plug-type connector. By way of defined short circuits between the individual contacts of the plug-type connector, the necessary configuration data, more particularly the latest firmware version, are then transferred to the sensor. For this purpose it is likewise necessary to use a separate programming device and this procedure is also relatively slow.

A proximity switch, by means of which both data and electrical energy are transferred via an electrical connection, is described in DE 41 23 828 C2. US 2005/0083741 A1 and U.S. Pat. No. 7,165,109 B2 relate to the functionality of USB components. In U.S. Pat. No. 7,165,109 B2 there is described a procedure in which a component connected to a USB interface of a computer prompts this computer to download a suitable driver for said component via the Internet. US 2006/0047465 describes a measuring device which is recognized by a computer as a USB mass storage device.

It is an object of the invention to provide a sensor to which configuration data can be transferred in a simpler manner than in the prior art. A further object is to provide a method for the simple transfer of configuration data to sensors from an external computer.

This object is achieved, in a first aspect of the invention, by the sensor having the features of claim 1. In a second aspect of the invention, the object is achieved by the method having the features of claim 11.

Preferred embodiments of the sensor of the invention and advantageous variants of the method of the invention are the subject matter of the dependent claims and are in addition explained in the following description, particularly with reference to the FIGURE.

The sensor of the aforementioned type is developed by the invention in that the computer interface is adapted for direct connection of the sensor to an external computer in a configuring mode, that in the configuring mode the sensor is supplied with electrical energy by the external computer via the computer interface, and that the computer interface is adapted to transfer, in the configuring mode, configuration data differentially between the sensor and the external computer via two wires of a data line at a bandwidth of greater than 1 MBit/s.

In the method of the invention for transferring configuration data from an external computer to a sensor, the sensor is connected via a computer interface, in a configuring mode, directly to an external computer and is supplied with electrical energy by said external computer. Furthermore, in the configuring mode configuration data are transferred via two wires of a data line with a bandwidth greater than 1 MBit/s differentially between the sensor and the external computer. The same computer interface is adapted for an operating mode for connecting the sensor to a programmable logic control unit or to a bus system, and, in the operating mode, the sensor is supplied with electrical energy by the peripheral unit via the computer interface.

An essential concept of the invention may first of all be regarded as being the realization that the presently available microcontrollers and memory modules have sufficiently large memory capacities for software for different functionalities of the computer interface to be placed therein.

A further fundamental idea of the invention may be regarded as being the multifunctional adaptation of the computer interface of the sensor such that the sensor can be connected via one and the same computer interface both to a peripheral unit and to the external computer by means of which the configuration is carried out.

An essential advantage of the invention can be regarded as being that between the sensor and the external computer there is no longer any need for additional programming devices, such as protocol converters, interface converters, or programming devices for intermittent short-circuiting and components pertaining thereto, such as power supply units.

Another advantage is that a greater interference immunity is achieved and thus the necessary configuration data can be transferred at a higher speed to the respective sensors.

It is particularly preferred that, in the configuring mode, standard protocols can be implemented so that no further development work is necessary.

The sensor element can basically be any element suitable for detecting a physical variable. For example, the sensor element can be a coil or an oscillator circuit of an inductive proximity switch, a photodetector of an optical sensor, a capacitive probe, or a thermocouple.

Accordingly, the sensors can be basically any kind of sensors for detecting a measurand or for detecting objects or articles. It is particularly advantageous to make use of the present invention for sensors used in the industrial sector, for example, inductive, capacitive, or optical sensors, temperature sensors, or pressure sensors. For example, they can be identification sensors such as RFID reading heads.

The term “configuration” should, for the purposes of the present description, be taken to mean any alteration or adjustment of the sensor as effected by a software program. This comprises, in particular, any transference of program code or binary code to the sensor and uploading of firmware and modification and/or addition of parameters.

The configuring mode always involves a configuration procedure which can basically also take place during the measuring operation. Accordingly, the configuring and operating modes can overlap in time and can thus be carried out simultaneously.

Basically, the peripheral unit can be a relay, other switchgear or control equipment, a power supply or an evaluating unit or a bus system. In most cases, the sensor will be connected, in the operating mode, to a programmable logic control unit as the peripheral unit.

For the purposes of the present description, the term “computer interface” should be taken to mean those components which are necessary to establish a data link between the sensor and the external computer or between the sensor and a peripheral unit. According to the invention, this interfaced connection is also adapted to transfer electrical energy for the supply of the sensor.

Thus, the computer interface preferably comprises hardware, especially a plug-type connector, as well as software, which is stored in the control/evaluation unit.

The term “control/evaluation unit” is to be understood to mean essentially all intelligent electronic components of the sensor. In principle, the control/evaluation unit can also be composed of a plurality of microcontrollers, FPGAs, CPLDs, GALs, or other programmable logic components, and optionally assigned memory modules by means of which various functionalities can be implemented, for example.

The transfer of data and energy can in principle be carried out wirelessly, e.g. per radio transmission. Theoretically, combinations are possible, so that for example the energy can be transmitted per cable and the data per radio transmission.

In advantageous embodiments of the sensor of the invention, however, plug-type connectors are provided as connecting means, through which both data and electrical energy can be passed. One particular advantage of the invention is that virtually any type of computer can be used as the external computer. For example, PCs can be used in the production process, and, in particular, customized parameter settings and tests on function can be carried out. Should reconfiguration or calibration be necessary at the site of action, it is preferred to use laptops, handhelds, or palmtops. Theoretically, a cellular phone could be used for this purpose.

Advantageously, no modifications have to be made to the housing or to the peripheral connections of the sensor in this case.

It is particularly preferred to use round plug-type connectors having a sealing effect as plug-type connectors for sensors used in automation technology. These can include, for example, 4- or 5-pin plug-type connectors, particularly V1 or V3 plug-type connectors.

Very preferably, the sensor is connected to a USB interface of the external computer for the configuring mode. The sensor is then recognized and treated, for example, as a mass storage device by the external computer. Also, the supply of electrical energy via the USB interface is possible. The control/evaluation unit then has a corresponding USB functionality, the external computer acting as the USB host and the sensor as the USB slave. The software e.g. stored in the control/evaluation unit is accordingly adapted to provide a USB slave functionality of the interface. This software can, in particular, be started automatically when the sensor is connected to the external computer.

In another particularly preferred variant, a configuring software program is stored in the memory of the control/evaluation unit, which can be uploaded into a RAM of an external computer when the sensor is connected to the external computer, and the configuring software program is set to effect configuration of the sensor, automatically or interactively by a user.

Advantageously, the sensor is temporarily connected to the external computer and the configuring software program stored in the memory of the sensor is then placed in the RAM of the computer, whereupon the sensor is configured with the aid of the configuring software program, automatically or by a user.

The fundamental idea of this development can be regarded as the sensor being autarkic in that the necessary software for configuring the sensor is contained in the sensor itself.

An important advantage of this arrangement is not only that no more additional programming devices are necessary, but also that no CD, DVDs or similar data media, on which the necessary parameterization or configuration programs are stored, need to be supplied. Finally, there is no need for the user to install software on the external computer when implementing the present invention. It is also advantageous that the invention can involve the use of conventional hardware and platform-independent software.

The configuration of the sensor or re-installation or supplementation of firmware on the sensor is particularly easily and simply carried out by causing the configuring software program to start automatically on the external computer when the sensor is connected to the external computer.

If the settings on the external computer do not allow for a fully automatic start of the configuring software program, provision may be preferably made for only minimum user interaction to be required for starting the configuring software program, for example merely by means of a single confirmation by the user by pressing the ENTER key.

The respective up-to-date versions of the firmware or configuring software program for the sensors can be stored on a server that can be accessed via the Internet. It is therefore particularly advantageous when the configuring software program stored on the sensor prompts the external computer to establish a network connection to a remote host and to check whether new program versions of the configuring software program and/or sensor firmware are available and optionally to download such up-to-date program versions from the remote host and to transfer the same to the memory of the sensor.

The configuring software program can basically be stored on the sensor in the form of executable code. In order to achieve greater independence from the external computer actually used, the configuring software program can be one which is very preferably capable of being executed platform-independently. For example, the configuring software program can be stored as interpretable code.

In order to make it possible to carry out the correct adjustments within the sensor and to switch the sensor to a configuring or measuring mode, it is advantageous when an electronic system is present that detects whether the sensor operatively communicates with a peripheral unit and/or whether the sensor is connected to an external computer. Such an electronic system can also reduce the risk of damage due to an excessively high voltage level at the contacts of the plug-type connectors that form the connecting means. Furthermore, in special situations in which the sensor is connected both to a peripheral unit and to an external computer, conflicts can be prevented, for example, between the peripheral unit and the external computer.

For this purpose, in a simple variant, the electronic system can analyze a supply voltage applied to at least one contact of the first or second connecting means. Additionally or alternatively, the electronic system can analyze a data signal present at a contact of the first or second connecting means. In principle, data signals present at a number of contacts of the first or second connecting means can be analyzed. On the whole, it is possible to determine in a reliable manner as to whether the sensor is operatively connected or whether the sensor is connected to an external computer.

Furthermore, the memory of the control/evaluation unit preferably comprises a read-only area. For example, a user manual can be stored therein which can be opened and viewed on the external computer when the sensor is connected to the latter. Such a user manual can be updated or supplemented in that new versions can be downloaded to the external computer via the Internet and then transferred to the sensor.

If the storage capacity of the control/evaluation unit used is not sufficient, additional memory modules can be used, if necessary.

Advantageously, a boot loader capable of effecting subsequent programming of the microcontroller is present or stored in the memory of the control/evaluation unit.

Other features and advantages of the invention are described below with reference to the attached diagrammatic drawing, in which:

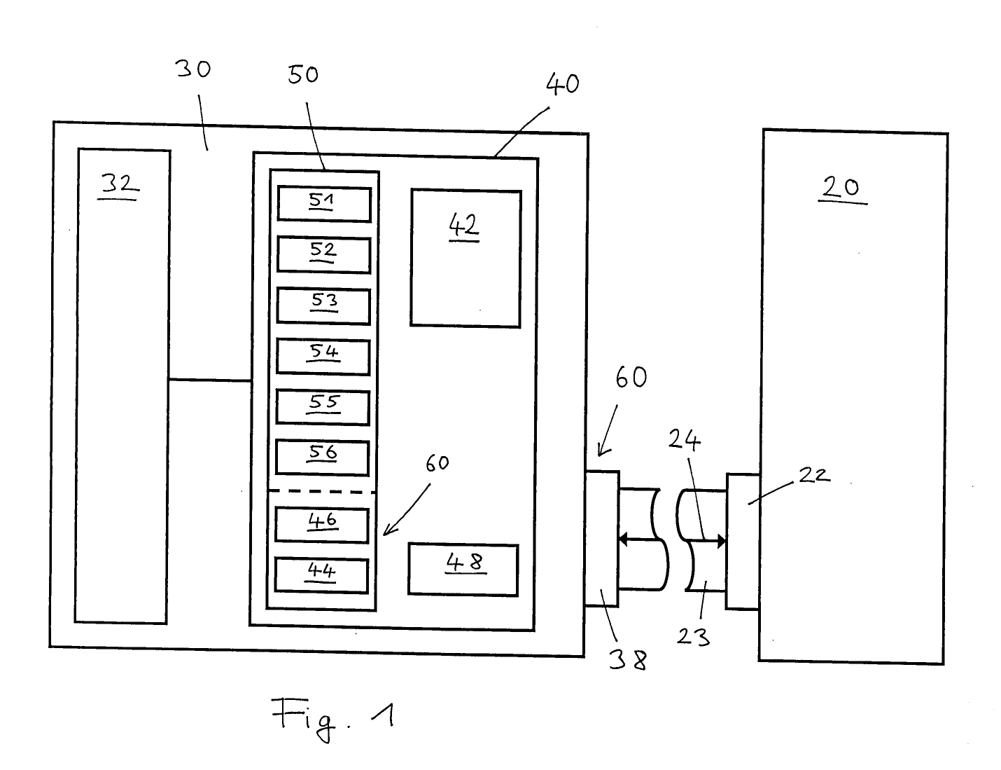

FIG. 1 is a diagrammatic view of an exemplary embodiment of a sensor of the invention.

The sensor 30 illustrated diagrammatically in FIG. 1 has as essential components a sensor element 32, for example, a coil, a control/evaluation unit 40 with a memory 50 and a plug-type connector 38 as part of a computer interface 60.

In the operating mode, the sensor 30 is connected via the plug-type connector 38 to a peripheral unit (not shown), for example a programmable logic control unit.

In the situation shown in FIG. 1, the sensor 30 is in a configuring mode and is connected via a USB cable 23 to a USB interface 22 of a computer 20, more particularly a PC. The double arrow 24 indicates that data and energy exchange can occur in both directions.

The control/evaluation unit 40 is a microcontroller having a flash memory as the memory 50. Currently, such microcontrollers are available which have a flash memory with a storage capacity of from 512 KB to 1 MB. Apart from storing the sensor firmware 52 and permanently stored data such as calibration data 54 and a parameter file 55, this large memory 50 provides sufficient space to store an independent configuring software program 56 which is intended, according to the invention, to permit convenient configuration and parameter-setting of the sensor 30.

Moreover, the memory 50 contains software modules 44, 46 as further components of the computer interface 60, which software modules provide the necessary interface functionalities when the sensor is connected to a programmable logic control unit or to a bus system or to a computer.

Furthermore, the memory 50 comprises a read-only area 51, in which, for example, a user manual for the sensor can be stored that can be viewed by a user on a monitor of this computer when the sensor 30 is connected to said computer 20. Furthermore, a software program 53, a so-called boot loader, which enables subsequent programming of the microcontroller, is provided in the memory 50.

As additional components, the control/evaluation unit 40 comprises a CPU 42 and an electronic system 48 that checks whether the sensor 30 operatively communicates with a peripheral unit or whether the sensor 30 is connected to an external computer 20, as in the situation illustrated. This electronic system 48 is not a demodulation circuit, since, in the present invention, the supply voltage and the data are fed through separate contacts of the plug-type connector 38. A USB operation can, for example, be determined by the use of a sensor operating voltage of 5 volts, which is far below the voltage range of from 10 to 30 volts DC that is customary for sensors. Accordingly, the electronic system 48 can cause the sensor to return to normal operation when the operating voltage is in the aforementioned range of from 10 to 30 volts and the sensor is accordingly connected to a peripheral unit. The supply voltages need not be applied to the same contacts of the plug-type connector 38, but instead it is basically also possible for the supply voltage to be each applied to different pins.

When the sensor 30 is connected to a programmable logic control unit or to a bus system, communication via the computer interface 60 is defined by the software program 46. Similarly, when the sensor 30 is connected to the USB interface 22 of the computer 20, the software program 44 becomes effective within the sensor 30, by means of which USB slave functionality is achieved.

According to the invention, data exchange with the computer 20 then takes place via a USB protocol, and in this configuring mode configuration data are transferred via two wires of the USB line 23 as data line with a bandwidth greater than 1 MBit/s differentially between the sensor and the external computer. Furthermore, the sensor 30 is provided, in this configuring mode, with electrical energy via the computer 20.

The sensor 30 can then act as a mass storage device and is handled by the PC accordingly. For example, the data can be stored in a file system in the memory 50. Such a file system can be recognized automatically by the operating system once the sensor 30 has been plugged into the interface 22 of the computer 20. Following the plug-in, the computer 20 can then access the files in the mass storage device in the usual manner. One of these files contains the configuring software program 56 which provides an easily operable graphical user interface and which is started on the computer 20 either automatically or optionally following user confirmation, i.e. with minimum user interaction, after the sensor 30 has been plugged into the computer 20. With the aid of this configuring software program 56, the sensor 30 can be interactively configured by a user and, for example, modifications can be made to the parameter file 55 and/or to the calibration data 54. The configuring software program 56 can be implemented, for example, in Java. The computer 20 can then run this program without any difficulty. Modifications and adjustments made by the user with the aid of the configuring software program 56 during the configuration phase can be stored permanently in, for example, an additional file in the memory 50 of the sensor 30. Access to this file is then possible with the aid of the sensor firmware 52 via a suitable interface during normal operation of the sensor, that is, when the sensor is connected to the peripheral unit.

The present invention provides a novel sensor and a method for configuring a sensor, a conventional round plug-type connector with a sealing effect being used, in particular, as an alternative means of communication with an external computer via a USB protocol. In a very preferred variant the sensor includes, in particular a graphical, parameterization tool or configuring software program which can be employed during manufacture of the sensor, but can also be used by the end user for configuration purposes. Due to the invention, firmware updates and updates of the configuring software program can be effected simultaneously and can also be carried out very conveniently, for example, by the end user himself, if necessary.

Theoretically, it is possible to provide an additional plug-type connector on the sensor housing to achieve the USB connection to the external computer. Other interfaces or protocols such as Firewire can likewise be used. Very preferably, USB protocols and developments or variants thereof are used. Finally, a wireless interface to the external computer is theoretically possible.

1-18. (canceled)

19. A sensor for use in automation technology for detection of a measurand, comprising:
a sensor element for measuring a physical variable;
a control/evaluation unit for controlling the sensor element, for processing a measuring signal from the sensor element, and for outputting an output signal to a computer interface;
wherein the control/evaluation unit includes a memory for storing at least configuration data and program data, the control/evaluation unit cooperating, in an operating mode, with the computer interface for connecting the sensor to a peripheral unit, and wherein the sensor is supplied with electrical energy by the peripheral unit, in the operating mode;
wherein
the computer interface is adapted for use in a configuring mode for direct connection of the sensor to an external computer;
the sensor is supplied with electrical energy by the external computer via the computer interface, in the configuring mode; and
the computer interface is adapted to transfer, in the configuring mode, configuration data differentially between the sensor and the external computer through two wires of a data line at a bandwidth of more than 1 MBit/s.

20. The sensor according to claim 19,
wherein
the computer interface has hardware means and software that is stored in the control/evaluation unit.

21. The sensor according to claim 19,
wherein
the computer interface has a plug-type connector and software that is stored in the control/evaluation unit.

22. The sensor according to claim 20,
wherein
the software is adapted to provide a USB slave functionality of the computer interface when the sensor is connected to the external computer.

23. The sensor according to claim 20,
wherein
the software is adapted to provide automatically a USB slave functionality of the computer interface when the sensor is connected to the external computer.

24. The sensor according to claim 19,
wherein
in the memory of the control/evaluation unit there is stored configuring software, which can be uploaded into a RAM of the external computer when the sensor is connected to the external computer; and
the configuring software is adapted for automatic configuration of the sensor.

25. The sensor according to claim 19,
wherein
in the memory of the control/evaluation unit there is stored configuring software, which can be uploaded into a RAM of the external computer when the sensor is connected to the external computer; and
the configuring software is adapted for configuration of the sensor interactively by a user.

26. The sensor according to claim 19,
further comprising:
an electronic system for recognizing whether the sensor operatively communicates with the peripheral unit.

27. The sensor according to claim 19,
further comprising:
an electronic system for recognizing whether the sensor is connected to the external computer.

28. The sensor according to claim 19,
further comprising:
an electronic system for recognizing whether the sensor operatively communicates with the peripheral unit and whether the sensor is connected to the external computer.

29. The sensor according to claim 26,
wherein
the electronic system analyzes a supply voltage applied to at least one contact of the computer interface.

30. The sensor according to claim 26,
wherein
the electronic system analyzes a data signal applied to at least one contact of the computer interface.

31. The sensor according to claim 19,
wherein
the memory of the control/evaluation unit has a read-only area.

32. The sensor according to claim 19,
wherein
the plug-type connector is a round plug-type connecter having a sealing action.

33. The sensor according to claim 19,
wherein
a boot loader is present in the memory of the control/evaluation unit.

34. The sensor according to claim 19, which is configured for the detection of objects or articles,
wherein the sensor is connected via the computer interface, in the configuring mode, directly to the external computer and is supplied with electrical energy by the external computer;
wherein configuration data are differentially transferred between the sensor and the external computer in the configuring mode via the two wires of the data line at a bandwidth of more than 1 MBit/s;
wherein the same computer interface is adapted to connect the sensor to the peripheral unit in the operating mode; and
wherein the sensor is supplied with electrical energy, in the operating mode, by the peripheral unit via the computer interface.

35. A method for transferring configuration data from an external computer to a sensor for automation technology,
wherein the sensor is connected via a computer interface, in a configuring mode, directly to an external computer and is supplied with electrical energy by the external computer;
wherein configuration data are differentially transferred between the sensor and the external computer in the configuring mode via two wires of a data line at a bandwidth of more than 1 MBit/s;
wherein the same computer interface is adapted to connect the sensor to a peripheral unit in an operating mode; and
wherein the sensor is supplied with electrical energy, in the operating mode, by the peripheral unit via the computer interface.

36. The method according to claim 35,
wherein
the sensor is temporarily connected to the external computer;
configuring software stored in a memory of the sensor then is uploaded into a RAM of the computer; and
the sensor is then automatically configured using the configuring software.

37. The method according to claim 35,
wherein
the sensor is temporarily connected to the external computer;
configuring software stored in a memory of the sensor then is uploaded into a RAM of the computer; and
the sensor is then configured by a user using the configuring software.

38. The method according to claim 35,
wherein
the sensor is recognized and treated by the external computer as a mass memory.

39. The method according to claim 35,
wherein
the sensor is connected, in the configuring mode, to a USB interface of the external computer.

40. The method according to claim 35,
wherein
in the memory of the control/evaluation unit there is stored software adapted to impart USB slave functionality to the computer interface, wherein the software is started when the sensor is connected to the external computer.

41. The method according to claim 35,
wherein
after the sensor has been connected to the external computer, the configuring software is started on the external computer following confirmation by a user.

42. The method according to claim 35,
wherein
after the sensor has been connected to the external computer, the configuring software is automatically started on the external computer.

43. The method according to claim 35,
wherein
the configuring software program prompts the external computer to establish a network connection to a remote host and to check whether at least one of new program versions for the configuring software program and new sensor firmware are available and
any up-to-date program versions are downloaded from the remote host and transferred to the memory of the sensor.

44. The method according to claim 35,
wherein
the configuring software program is stored in the memory of the sensor as an executable or interpretable program.

45. The method according to claim 35 for transferring configuration data from an external computer to a sensor, wherein the sensor comprises:
a sensor element for measuring a physical variable;
a control/evaluation unit for controlling the sensor element, for processing a measuring signal from the sensor element, and for outputting an output signal to the computer interface;
wherein the control/evaluation unit includes a memory for storing at least configuration data and program data, the control/evaluation unit cooperating, in the operating mode, with the computer interface for connecting the sensor to the peripheral unit, and wherein the sensor is supplied with electrical energy by the peripheral unit, in the operating mode;
wherein
the computer interface is adapted for use in the configuring mode for direct connection of the sensor to the external computer;
the sensor is supplied with electrical energy by the external computer via the computer interface, in the configuring mode; and
the computer interface is adapted to transfer, in the configuring mode, configuration data differentially between the sensor and the external computer through two wires of a data line at a bandwidth of more than 1 MBit/s.
